(19) United States
(12) Patent Application Publication
(10) Pub. No.: US 2021/0011514 A1
(43) Pub. Date: Jan. 14, 2021

(54) BENDABLE MECHANISM AND FLEXIBLE DISPLAY DEVICE

(71) Applicant: SHENZHEN ROYOLE TECHNOLOGIES CO. LTD., Shenzhen (CN)

(72) Inventors: Zhengxi WANG, Shenzhen (CN); Songya CHEN, Shenzhen (CN); Songling YANG, Shenzhen (CN); Xiaofei FAN, Shenzhen (CN); Weifeng WU, Shenzhen (CN); Qiang ZHANG, Shenzhen (CN)

(21) Appl. No.: 17/016,218

(22) Filed: Sep. 9, 2020

Related U.S. Application Data
(63) Continuation of application No. PCT/CN2018/112679, filed on Oct. 30, 2018.

(30) Foreign Application Priority Data
Mar. 12, 2018 (CN) PCT/CN2018/078689
Mar. 12, 2018 (CN) PCT/CN2018/078690
Mar. 12, 2018 (CN) PCT/CN2018/078691
May 25, 2018 (CN) PCT/CN2018/088517

(51) Int. Cl. G06F 1/16; H05K 5/02

(52) U.S. Cl. CPC G06F 1/1618; H05K 5/0226; G06F 1/1681; G06F 1/1652

(57) ABSTRACT

A bendable mechanism and a flexible display device are provided. The bendable mechanism includes a rotating shaft assembly, a sliding rail assembly, and a casing. The sliding rail assembly connects the casing with the rotating shaft assembly. The bendable mechanism is operable to be switched between an unfolded status and a folded status. During switching the bendable mechanism from the unfolded status to the folded status, the rotating shaft assembly and the casing move relatively close to each other under the guiding of the sliding rail assembly, and during switching the bendable mechanism from the folded status to the unfolded status, the rotating shaft assembly and the casing move relatively away from each other under the guiding of the sliding rail assembly.

### CROSS-REFERENCE TO RELATED APPLICATION(S)

This application is a continuation of International application No. PCT/CN2018/112679, submitted on Oct. 30, 2018, which claims priority to International Application No. PCT/CN2018/078690, PCT/CN2018/078691, and PCT/CN2018/078689, all submitted on Mar. 12, 2018, and International Application No. PCT/CN2018/088517, submitted on May 25, 2018, the disclosures of all of which are hereby incorporated by reference in their entireties.

### TECHNICAL FIELD

This disclosure relates to the field of flexible screen supporting, and particularly to a bendable mechanism and a flexible display device.

### BACKGROUND

Flexible screens are increasingly favored by consumers due to advantages of the flexible screens, for example, the flexible screen can be bent and stretched and designed as a curved screen. The flexible screen needs to be supported by a bendable structure during bending of the flexible screen. Thus, there is a need to provide a bendable structure suitable for the flexible screen.

### SUMMARY

In view of the above, implementations of the disclosure provide a bendable mechanism which is suitable for a flexible screen and a flexible display device.

The bendable mechanism of implementations of the disclosure includes a rotating shaft assembly, a sliding rail assembly, and a casing. The sliding rail assembly connects the casing with the rotating shaft assembly. The bendable mechanism is able to be switched between an unfolded status and a folded status. During switching the bendable mechanism from the unfolded status to the folded status, the rotating shaft assembly and the casing move relatively close to each other under the guiding of the sliding rail assembly, and during switching the bendable mechanism from the folded status to the unfolded status, the rotating shaft assembly and the casing move relatively away from each other under the guiding of the sliding rail assembly. The sliding rail assembly includes at least two sliding rails that are disposed in parallel, where the at least two sliding rails are operable to guide relative movement between the rotating shaft assembly and the casing.

The flexible display device of the implementations of the disclosure includes the bendable mechanism described in the above implementations, a flexible support member, and a flexible screen. The flexible support member is secured to the bendable mechanism. The flexible screen is attached to a surface of the flexible support member away from the bendable mechanism.

For the bendable mechanism and the flexible display device in the implementation of the disclosure, during bending the bendable mechanism, since the rotating shaft assembly and the casing move relatively close to each other under the guiding of the sliding rail assembly, a change in arc length of the bending portion of the rotating shaft assembly during bending the rotating shaft assembly can be offset, thereby preventing the flexible screen arranged on the bendable mechanism from being damaged by stretching. In addition, since the relative movement between the rotating shaft assembly and the casing are guided by the at least two sliding rails arranged in parallel, the relative movement between the rotating shaft assembly and the casing may have high stability, such that the service life of the flexible screen can be ensured. Furthermore, it is possible to enable the flexible screen to be flattened when the rotating shaft assembly is in the unfolded status.

### BRIEF DESCRIPTION OF THE DRAWINGS

The above and/or additional aspects and advantages of the disclosure will become apparent and easily understood with reference to the description of the implementations described in conjunction with the accompanying drawings.

FIG. 1 is a front view of a flexible display device in an unfolded status according to implementations of the present disclosure.

FIG. 2 is a rear view of the flexible display device in the unfolded status according to implementations of the present disclosure.

FIG. 3 is a perspective view of the flexible display device in the folded status according to implementations of the present disclosure.

FIG. 4 is an exploded, perspective view of the flexible display device according to implementations of the present disclosure.

FIG. 5 is a perspective view of a bendable mechanism according to implementations of the present disclosure.

FIG. 6 is an enlarged view of part VI illustrated in in FIG. 5.

FIG. 7 is a perspective view of the bendable mechanism in a folded status according to implementations of the present disclosure.

FIG. 8 is an exploded, perspective view illustrating part of the bendable mechanism according to implementations of the present disclosure.

FIG. 9 is an enlarged view of part IX illustrated in FIG. 8.

FIG. 10 is a perspective view of a rotating shaft assembly when the bendable mechanism is in an unfolded status according to implementations of the present disclosure.

FIG. 11 is an exploded view of the rotating shaft assembly according to implementations of the present disclosure.

FIG. 12 is a perspective view of a first sliding member according to implementations of the present disclosure.

FIG. 13 a perspective view of the first sliding member viewed from another viewpoint.

FIG. 14 is an exploded, perspective view of a sliding rail assembly according to implementations of the present disclosure.

FIG. 15 is an exploded, perspective view of a guide rail assembly according to implementations of the present disclosure.

### DETAILED DESCRIPTION

The following describes implementations in detail. Examples of the implementations are illustrated in the accompanying drawings, where throughout the specification the same or like reference numerals represent the same or like elements or elements having the same or similar functions. The implementations described below with reference to the accompanying drawings are exemplary and merely intended to explain the disclosure rather than limit the disclosure.

In the following description, it should be understood that directions or positional relationships indicated by terms “center”, “longitudinal”, “transverse”, “length”, “width”, “thickness”, “upper”, “lower”, “front”, “rear/back”, “left”, “right”, “vertical”, “horizontal”, “top”, “bottom”, “inner”, “outer”, “clockwise”, and “counterclockwise” are based on directions or positional relationships illustrated in the accompany drawings. The terms are merely for the convenience of describing the disclosure and simplifying the description, and do not indicate or imply that the device or elements indicated must have a specific orientation and need to be constructed and operated in the specific orientation. Therefore, the terms cannot be understood as a restriction on this disclosure. In addition, terms “first”, “second”, and the like are merely used for describing purposes, and cannot be understood as indicating or implying relative importance or implicitly indicating the number of indicated technical features. Therefore, the features defined with “first” and “second” may explicitly or implicitly include one or more of the features. In the description of the disclosure, “multiple/a plurality of/a number of” means two or more than two, unless otherwise specifically defined.

The following describes many different implementations or examples for realizing different structures of the disclosure. To simplify the disclosure, the following merely describes components and settings of specific examples. Certainly, it can be understood that those implementations or examples are merely illustrative and not intended to limit the disclosure. In addition, in different implementations of the disclosure, reference can be made to same reference numbers and/or reference letters, and this repetition is for the purpose of simplification and clarity, and does not indicate the relationships between various implementations and/or settings discussed. In addition, various examples of specific processes and materials are illustrated in the disclosure, but those of ordinary skill in the art may be aware of the application of other processes and/or the use of other materials.

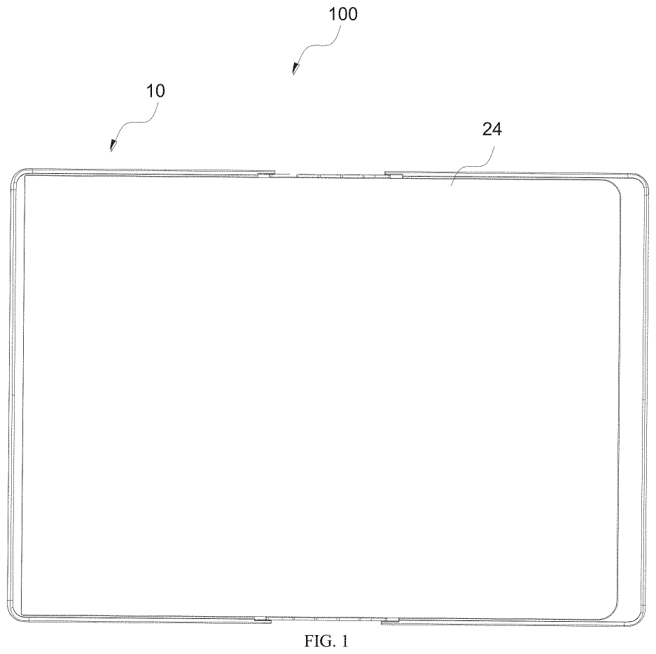

Referring to FIG. 1 to FIG. 4, a bendable mechanism 10 and a flexible display device 100 are provided in an implementation of the present disclosure. The flexible display device 100 includes the bendable mechanism 10 and a flexible screen 24. The flexible screen 24 is attached with the bendable mechanism 10. The flexible screen 24 of the flexible display device 100 can be used for display. The flexible display device 100 includes, but is not limited to, a display device such as a mobile phone, a tablet computer, a bendable wearable device, or the like.

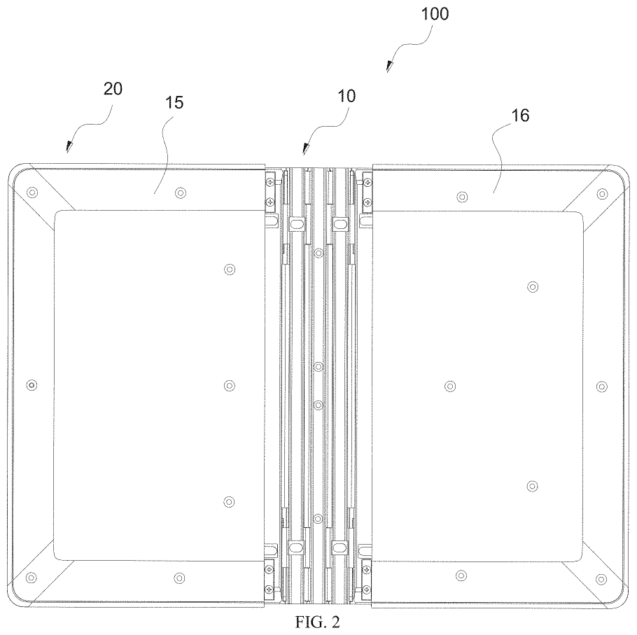

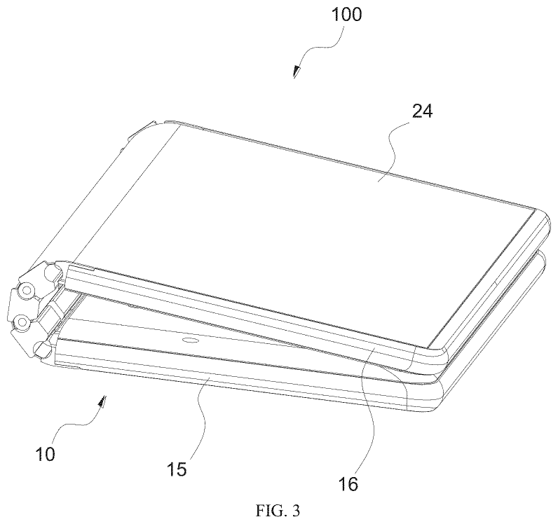

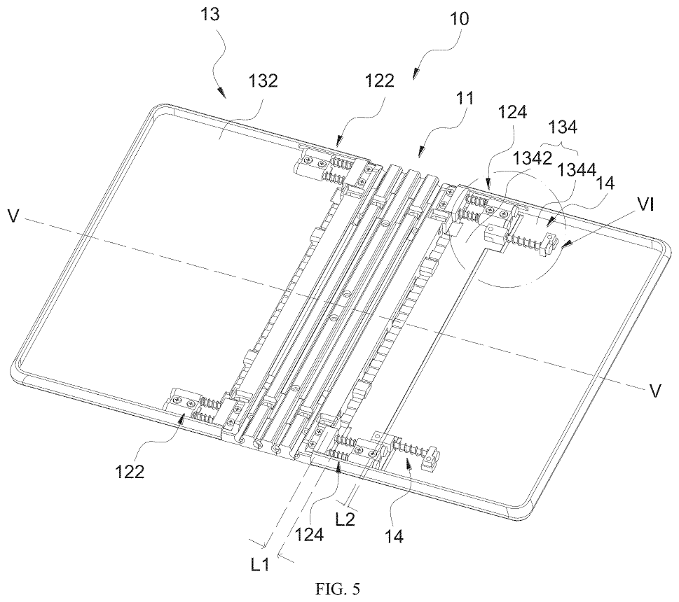

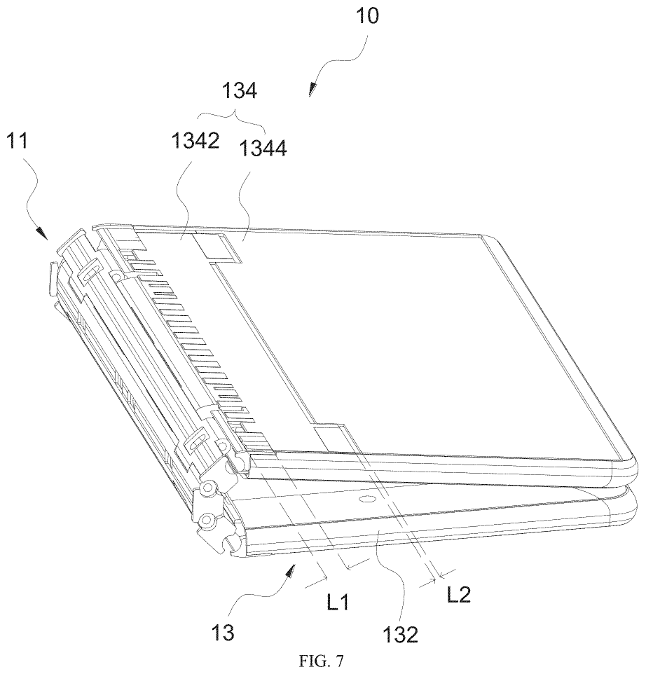

Referring to FIG. 5 to FIG. 7, the bendable mechanism 10 includes a rotating shaft assembly 11, a sliding rail assembly 12, a casing 13, and a guide rail assembly 14. The casing 13 includes a first sliding member 1342 and a second sliding member 1344. The sliding rail assembly 12 is coupled with the first sliding member 1342 and the rotating shaft assembly 11. The guide rail assembly 14 is coupled with the first sliding member 1342 and the second sliding member 1344. The rotating shaft assembly 11 is able to be switched between an unfolded status (as illustrated in FIG. 1, FIG. 2, and FIG. 5) and a folded status (as illustrated in FIG. 3 and FIG. 7). During switching the rotating shaft assembly 11 from the unfolded status to the folded status, the rotating shaft assembly 11 and the first sliding member 1342 move relatively close to each other under the guiding of the sliding rail assembly 12, and the first sliding member 1342 and the second sliding member 1344 move relatively close to each other under the guiding of the guide rail assembly 14. During switching the rotating shaft assembly 11 from the folded status to unfolded status, the rotating shaft assembly 11 and the first sliding member 1342 move relatively away from each other under the guiding of the sliding rail assembly 12, and the first sliding member 1342 and the second sliding member 1344 move relatively away from each other under the guiding of the guide rail assembly 14.

For the bendable mechanism 10 and the flexible display device 100 in the implementation of the present disclosure, during bending the bendable mechanism 10, since the rotating shaft assembly 11 and the first sliding member 1342 move relatively close to each other under the guiding of the sliding rail assembly 12, and the first sliding member 1342 and the second sliding member 1344 move relatively close to each other under the guiding of the guide rail assembly 14, a change in arc length of a bending portion of the rotating shaft assembly 11 during bending the rotating shaft assembly 11 can be offset, thereby preventing the flexible screen 24 arranged on the bendable mechanism 10 from being damaged by stretching and ensuring the service life of the flexible screen 24. Furthermore, it is possible to enable the flexible screen 24 to be flattened when the rotating shaft assembly 11 is in the unfolded status.

The change in the length of the curved surface of the rotating shaft assembly 11 after being bent can be offset by changes in a first distance L1 between the rotating shaft assembly 11 and the first sliding member 1342 and a second distance L2 between the first sliding member 1342 and the second sliding member 1344, to make a total length of the flexible display device 100 unchanged, thereby preventing the flexible screen 24 from being damaged by stretching. When the bendable mechanism 10 is flattened, the first distance L1 reaches a maximum value. When the bendable mechanism 10 is gradually bent, the first sliding member 1342 slides close to the rotating shaft assembly 11, and thus the first distance L1 decreases. In addition, the second sliding member 1344 may slide towards the first sliding member 1342, and the first sliding member 1342 may slide towards the rotating shaft assembly 11. In other words, the first sliding member 1342 may slide relatively close to or away from the second sliding member 1344. Therefore, the second distance L2 between the first sliding member 1342 and the second sliding member 1344 may decrease or increase, which is dependent on a sliding distance that the first sliding member 1342 moves towards the rotating shaft assembly 11 and a sliding distance that the second sliding member 1344 moves towards the rotating shaft assembly 11. However, no matter how the second distance L2 changes, a flexible screen 24 always can be prevented from being excessively stretched, thereby enabling smooth unfolding and folding of the flexible display device 100.

According to implementations, when the rotating shaft assembly 11 is in the unfolded status, the first distance L1 between the rotating shaft assembly 11 and the first sliding member 1342 is larger than the second distance L2 between the first sliding member 1342 and the second sliding member 1344.

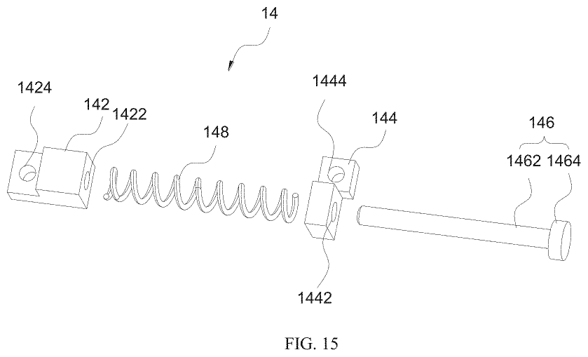

Referring to FIG. 5 and FIG. 15, in at least one implementation, the guide rail assembly 14 includes a fixing member 142, a guide base 144, and a guide rail 146. The fixing member 142 is secured to the first sliding member 1342. The guide base 144 is secured to the second sliding member 1344. The guide rail 146 is slidably coupled with the guide base 144. The guide rail 146 is secured to the fixing member 142.

In one example, the fixing member 142 can be secured to the first sliding member 1342 in a manner such as welding, gluing, screwing, riveting, and so on (as illustrated in FIG. 5, each fixing member 142 is secured to a position of the first sliding member 1342 close to one of two ends of the first sliding member 1342). The guide base 144 can be secured to the second sliding member 1344 in a manner such as welding, gluing, screwing, riveting, and so on (as illustrated in FIG. 5, each guide base 144 is secured to a position of the second sliding member 1344 close to one of two ends of the second sliding member 1344). The guide base 144 defines a first through hole 1442. The guide rail 146 passes through the first through hole 1442 to be slidably coupled with the guide base 144. That is, the guide base 144 can slide along the guide rail 146, resulting in relative movement between the guide rail 146 and the guide base 144, such that the fixing member 142 and the guide base 144 are able to move relatively close to or move relatively away from each other under the guiding of the guide rail 146, and the first sliding member 1342 and the second sliding member 1344 are able to move relatively close to or move relatively away from each other under the guiding of the guide rail assembly 14. The fixing member 142 defines a first recess 1422. One end of the guide rail 146 is inserted in the first groove 1422 and can be fixed to the fixing member 142 by welding, gluing, screwing, riveting, or the like.

According to implementations, the fixing member 142 further defines a fourth through hole 1424. The fixing member 142 is fixed to the first sliding member 1342 by inserting a screw in the fourth through hole 1424 defined in the fixing member 142. The guide base 144 further defines a fifth through hole 1444. The guide base 144 is fixed to the second sliding member 1344 by inserting a screw in the fifth through hole 1444 defined in the guide base 144. According to implementations, since the fixing member 142 is fixed to the first sliding member 1342 via the screw, and the guide base 144 is fixed to the second sliding member 1344 via the screw, it is convenient for disassembly and assembly. In addition, the bendable mechanism 10 has high stability.

Referring to FIG. 5 and FIG. 15, in at least one implementation, the guide rail assembly 14 further includes an elastic member 148. The elastic member 148 is sleeved on the guide rail 146. The elastic member 148 is disposed between the fixing member 142 and the guide base 144 and can apply an elastic force to the fixing member 142 and the guide base 144, to enable the fixing member 142 and the guide base 144 to move relatively away from each other.

In one example, during switching the bendable mechanism 10 from the unfolded status to the folded status, the elastic member 148 is compressed, and during switching the bendable mechanism 10 from the folded status to the unfolded status, the elastic member 148 extends. During unfolding of the bendable mechanism 10, the elastic member 148 can provide a push force to cause the first sliding member 1342 and the second sliding member 1344 to move relative to each other smoothly and stably, so as to enable smooth unfolding of the bendable mechanism 10, thereby preventing the flexible screen assembly 20 from being warped. When the bendable mechanism 10 is in the unfolded status, the elastic member 148 is in a natural state (that is, a state where no force is generated by the elastic member 148) or a compressed state. The elastic member 148 being sleeved on the guide rail 146 can save a space for stacking in the bendable mechanism 10 and improve a space utilization rate of the bendable mechanism 10, thereby facilitating installation of other elements.

In one example, one end of the elastic member 148 is fixed to the fixing member 142 and the other end of the elastic member 148 is fixed to the guide base 144. Alternatively, both ends of the elastic member 148 are not fixed. Alternatively, one end of the elastic member 148 is fixed to the fixing member 142 or the guide base 144, and the other end of the elastic member 148 is not fixed. According to implementations, the elastic member 148 is sleeved on the guide rail 146, and both ends of the elastic member 148 are not fixed, which is convenient for disassembly and assembly. It can be understood that there is no restriction on the assembly manner of the elastic member 148, and different assembly manners can be adopted according to actual needs.

The elastic member 148 may have a straight-line shape. The straight-line shape refers to appearance of the elastic member 148 in the natural state. The cooperation of the fixing member 142, the guide rail 146, and the guide base 144 can position the elastic member 148, so that the elastic member 148 can be deformed in a preset direction (i.e., an extending direction (a sliding direction) of the guide rail 146), enabling relative movement between the first sliding member 1342 and the second sliding member 1344 under the guiding of the guide rail 146.

According to implementations, the direction in which the elastic member 148 is deformed is parallel to the sliding direction of the guide rail 146. In this way, it is possible to ensure that the bendable mechanism 10 has high stability when the first sliding member 1342 and the second sliding member 1344 move relative to each other. In one example, when the bendable mechanism 10 is switched from the folded status to the unfolded status, the elastic force generated by the elastic member 148 in the compressed state is exerted on the fixing member 142 and the guide base 144, and then the elastic force is transferred to the first sliding member 1342 and the second sliding member 1344, to enable the first sliding member 1342 and the second sliding member 1344 to move relative to each other.

Referring to FIG. 5 and FIG. 15, in at least one implementation, the guide rail 146 includes a guide rod 1462 and a limitation head 1464. The guide rod 1462 passes through the guide base 144. One distal end of the guide rod 1462 is secured to the fixing member 142, and the other distal end of the guide rod 1462 is coupled with the limitation head 1464. The limitation head 1464 is operable to abut against the guide base 144 to define a maximum distance of the relative movement between the first sliding member 1342 and the second sliding member 1344. The guide rod 1462 and the limitation head 1464 are integrally formed. Alternatively, the guide rod 1462 and the limitation head 1464 are separately formed. For example, the limitation head 1464 is secured to the guide rod 1462 by means of screwing, or the limitation head 1464 is secured to the guide rod 1462 by gluing, welding, or other manners.

In one example, the elastic member 148 is sleeved on the guide rod 1462. The guide base 144 can slide along the guide rod 1462. The guide base 144 is disposed between the elastic member 148 and the limitation head 1464.

When the first sliding member 1342 and the second sliding member 1344 move relatively close to each other, the limitation head 1464 and the guide base 144 may slide relatively away from each other, and the elastic member 148 is compressed by the guide base 144. When the first sliding member 1342 and the second sliding member 1344 move relatively away from each other, the limitation head 1464 and the guide base 144 move relatively close to each other, and the elastic member 148 gradually extends. The limitation head 1464 can prevent the guide rail 146 and the guide base 144 from being detached from each other when the first sliding member 1342 and the second sliding member 1344 move relatively away from each other. A cross-sectional area of the limitation head 1464 is larger than that of the first through hole 1442, so as to prevent the limitation head 1464 from passing through the first through hole 1442, thereby ensuring that the limitation head 1464 can play a position limiting role.

It can be understood that the maximum distance between the first sliding member 1342 and the second sliding member 1344 is smaller than a distance between the limitation head 1464 and the fixing member 142. In addition, the maximum distance between the first sliding member 1342 and the second sliding member 1344 is smaller than or equal to a length of the guide rod 1462.

In one example, the guide rail assembly 14 can be made of plastic or metal. For example, all elements of the guide rail assembly 14 are made of plastic. For another example, all elements of the guide rail assembly 14 are made of metal. For yet another example, some elements of the guide rail assembly 14 are made of metal, and the remaining elements of the guide rail assembly 14 are made of plastic. In this way, the guide rail assembly 14 can be made of a variety of materials, such that various demands can be achieved.

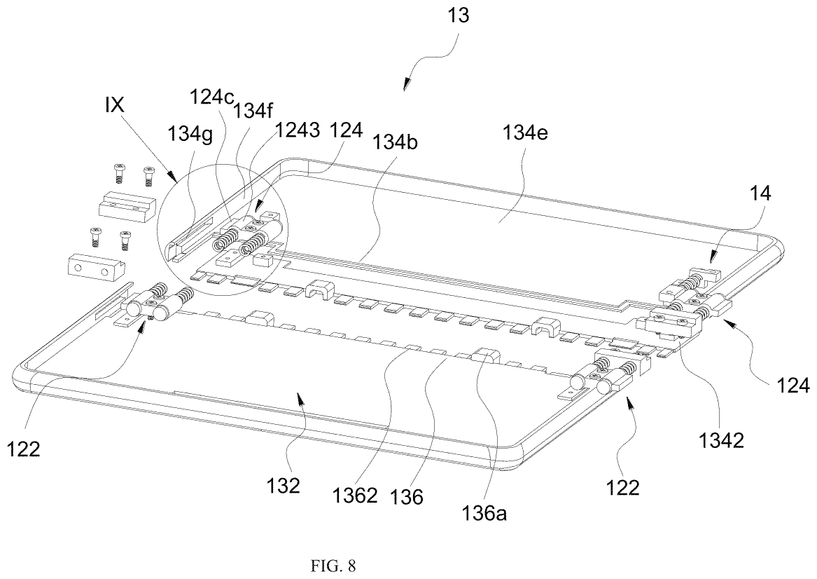

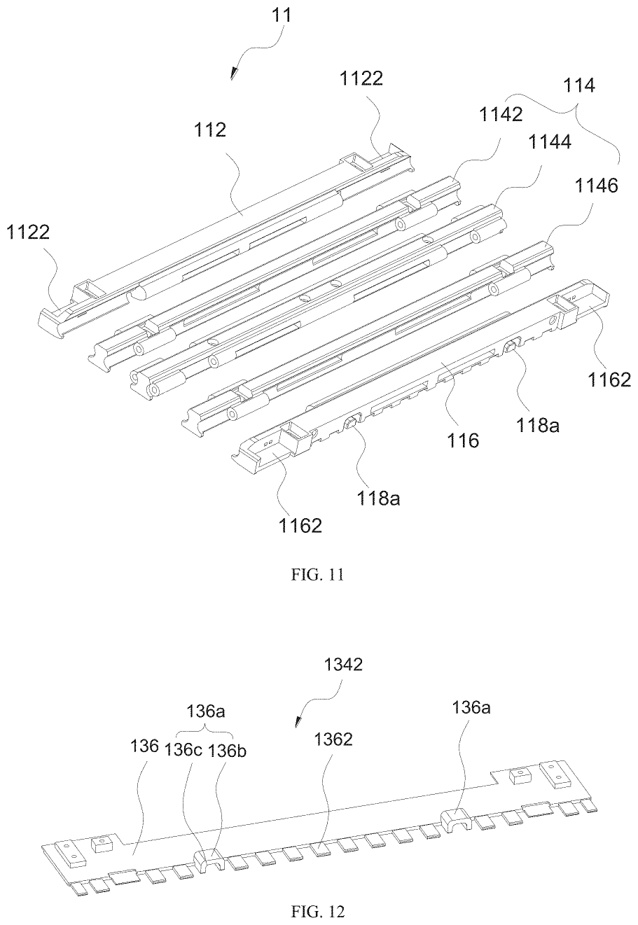

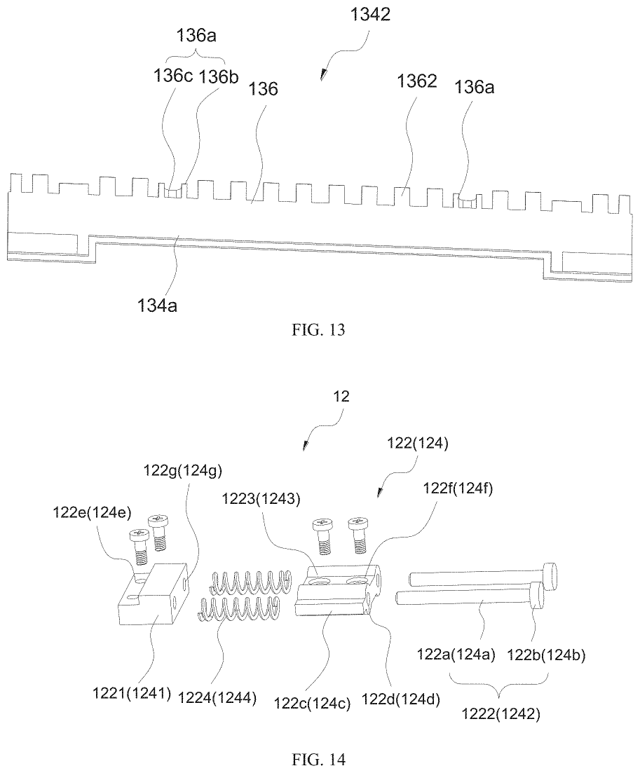

As illustrated in FIG. 8, FIG. 12, and FIG. 13, in at least one implementation, a first guide portion 134a is formed on a side of the first sliding member 1342 facing the second sliding member 1344, and a second guide portion 134b is formed on a side of the second sliding member 1344 facing the first sliding member 1342. When the rotating shaft assembly 11 is in the unfolded status, there is a gap between the first guide portion 134a and the second guide portion 134b, where the gap has a width of L2.

As illustrated in FIG. 5 and FIG. 7, as the first sliding member 1342 and the second sliding member 1344 move relatively close to or relatively away from each other, the first guide portion 134a and the second guide portion 134b may also move relatively close to or relatively away from each other, and accordingly, a distance between the first guide portion 134a and the second guide portion 134b is also relatively decreased or increased. The first guide portion 134a and the second guide portion 134b can cooperate with each other, to guide the relative movement between the first sliding member 1342 and the second sliding member 1344, so that the relative movement between the first sliding member 1342 and the second sliding member 1344 is relatively stable.

As illustrated in FIG. 8 and FIG. 13, in at least one implementation, the first guide portion 134a and the second guide portion 134b are stepped, and the first guide portion 134a and the second guide portion 134b are engaged with each other.

The first guide portion 134a and the second guide portion 134b that are both stepped can engage with each other to play a relatively good guiding role. In addition, connection between the first sliding member 1342 and the second sliding member 1344 is also relatively stable. There is no restriction on the shapes of the first guide portion 134a and the second guide portion 134b. The first guide portion 134a and the second guide portion 134b may be both in a shape such as a serration shape, a comb tooth shape, or other shapes, what is needed is that the first guide portion 134a and the second guide portion 134b can be engaged with each other, locked with each other, or fit together.

As illustrated in FIG. 5, in at least one implementation, there may be at least two guide rail assemblies 14. The at least two guide rail assemblies 14 are disposed on both sides of a central axis of the first sliding member 1342 and the second sliding member 1344.

The central axis is illustrated by a dotted line V in FIG. 5. The at least two guide rail assemblies 14 can provide a relatively good driving force and guiding function to ensure that the first sliding member 1342 and the second sliding member 1344 can slide smoothly. In addition, there is a relatively stable positional relationship between the first sliding member 1342 and the second sliding member 1344. That is, the first sliding member 1342 and the second sliding member 1344 are not easily to be detached from each other or misaligned to affect the movement cooperation of the first sliding member 1342 and the second sliding member 1344, thereby ensuring the smooth unfolding and folding of the bendable mechanism 10. Furthermore, during switching the bendable mechanism 10 to the folded status or the unfolded status, the movement of the first sliding member 1342 and the second sliding member 1344 is relatively stable.

In one example, there may be two guide rail assemblies 14. Each guide rail assembly 14 includes one fixing member 142, one guide rail 146, one elastic member 148, and one guide base 144. The two guide rail assemblies 14 are symmetrically arranged on both sides of the central axis of the first sliding member 1342 and the second sliding member 1344. With the above structure, the positional relationship between the first sliding member 1342 and the second sliding member 1344 may be relatively stable. In one example, there may be one guide rail assembly 14 to simplify the structure of the bendable mechanism 10. In another example, there may be more than one guide rail assembly 14 to make a sliding connection between the first sliding member 1342 and the second sliding member 1344 be relatively stable.

There is no restriction on the number of the fixing members 142, the guide rails 146, the elastic members 148, and the guide bases 144 of each guide rail assembly 14 and the number of the guide rail assemblies 14. The number of the fixing members 142, the guide rails 146, the elastic members 148, and the guide bases 144 of each guide assembly 14 and the number of the guide rail assemblies 14 can be specifically determined according to specific implementations as long as the smooth folding and unfolding of the bendable mechanism 10 and the stability of the sliding connection between the first sliding member 1342 and the second sliding member 1344 can be ensured.

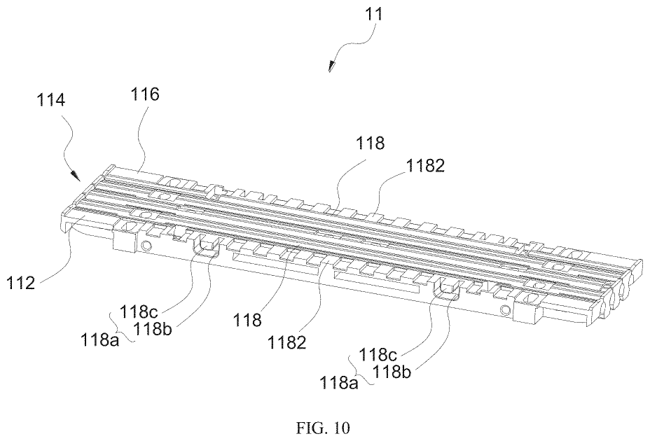

As illustrated in FIG. 5, FIG. 10, and FIG. 11, in at least one implementation, the rotating shaft assembly 11 includes a first connecting rotating shaft 116, a second connecting rotating shaft 112, and a middle rotating shaft structure 114. The casing 13 includes a second part 132 and a first part 134. The first connecting rotating shaft 116 and the second connecting rotating shaft 112 are respectively rotatably coupled with two opposite sides of the middle rotating shaft structure 114. In one example, there may be at least two sliding rail assemblies 12. The at least two sliding rail assemblies 12 are symmetrical with respect to a direction perpendicular to a bending line of the rotating shaft assembly 11, where the bending line is parallel to a extending direction of the two ends of the rotating shaft assembly 11. The sliding rail assembly 12 includes a first sliding rail assembly 124 and a second sliding rail assembly 122. The first sliding rail assembly 124 is coupled with the first connecting rotating shaft 116 and the first part 134. The second sliding rail assembly 122 is coupled with the second connecting rotating shaft 112 and the second part 132.

The second connecting rotating shaft 112 and the first connecting rotating shaft 116 are both hinged with the middle rotating shaft structure 114. In this way, the rotating shaft assembly 11 is of simple structure, and thus it can be easy to form the bendable mechanism 10 with a relatively simple structure, and accordingly, it is easy to form the flexible display device 100, such that the production cost and manufacturing difficulty may be reduced.

In one example, the casing 13 is made of metal or plastic. The casing 13 can be made of various materials and it is easy to obtain the casing 13, and thus it is beneficial to reduce the cost of the bendable mechanism 10. In addition, the casing 13 made of plastic or metal has a certain strength, which is beneficial to improve the strength and quality of the bendable mechanism 10, thereby improving the strength and quality of the flexible display device 100.

As illustrated in FIG. 5, FIG. 10, and FIG. 14, in one example, the second sliding rail assembly 122 includes a second connecting base 1221, a second sliding rail 1222, and a second sliding base 1223. The second connecting base 1221 is secured to the second connecting rotating shaft 112, and the second sliding base 1223 is secured to the second part 132. The second sliding rail 1222 is slidably coupled with the second sliding base 1223, and the second sliding rail 1222 is secured to the second connecting base 1221.

In one example, the second connecting base 1221 defines a first mounting hole 122e. The second connecting base 1221 can be secured to the second connecting rotating shaft 112 by screwing, that is, the second connecting base 1221 can be secured to the second connecting rotating shaft 112 by inserting a screw in the first mounting hole 122e. The second sliding base 1223 defines a second mounting hole 122f. The second sliding base 1223 can be secured to the second part 132 by screwing, that is, the second sliding base 1223 can be secured to the second part 132 by inserting a screw in the second mounting hole 122f. According to implementations, since the second connecting base 1221 is fixed to the second connecting rotating shaft 112 via the screw, and the second sliding base 1223 is fixed to the second part 132 via the screw, it is convenient for disassembly and assembly. In addition, the bendable mechanism 10 has high stability.

The second connecting base 1221 can be secured to the second connecting rotating shaft 112 by welding, gluing, riveting, or the like. The second sliding base 1223 can be secured to the second part 132 by welding, gluing, riveting, or the like. The second sliding base 1223 defines at least one third through hole 122d. Each second sliding rail 1222 passes through a corresponding third through hole 122d to be slidably coupled with the second sliding base 1223. The second sliding rail 1222 can move linearly in the third through hole 122d to cause the second sliding rail 1222 and the second sliding base 1223 to move relative to each other, such that the second connecting base 1221 and the second sliding base 1223 move relatively close to or away from each other under the guiding of the second sliding rail 1222. The second connecting base 1221 defines a second recess 122g. One end of the second sliding rail 1222 is inserted in the second recess 122g and secured to the second connecting base 1221 by welding, gluing, screwing, or riveting. Therefore, the second connecting rotating shaft 112 and the second part 132 can also move relatively close to or away from each other under the guiding of the second sliding rail assembly 122.

As illustrated in FIG. 11, the second connecting rotating shaft 112 defines a second mounting groove 1122 at a position facing the second connecting base 1221. The second connecting base 1221 is inserted in the second mounting groove 1122, which improves the space utilization of the second connecting rotating shaft 112 and ensures that the second connecting rotating shaft 112 has a relatively smooth surface, facilitating the subsequent deployment of the flexible screen assembly 20.

As illustrated in FIG. 14, in one example, the second sliding rail assembly 122 includes at least two second sliding rails 1222 that are parallel to each other. The at least two second sliding rails 1222 are operable to guide relative movement between the rotating shaft assembly 11 and the second part 132. The at least two second sliding rails 1222 being arranged in parallel can ensure that each second sliding rail 1222 can slide in the second sliding base 1223 smoothly, so that the movement between the rotating shaft assembly 11 and the second part 132 is relatively stable and smooth.

It can be understood that there may be multiple second sliding rails 1222 that are arranged in parallel. The multiple second sliding rails 1222 (arranged in parallel) are spaced apart from each other and disposed on the second sliding base 1223 and the second connecting base 1221. Alternatively, the second sliding rail assembly 122 includes one second sliding rail 1222. According to implementations, each second sliding rail assembly 122 includes one second connecting base 1221, one second sliding base 1223, and two second sliding rails 1222. Alternatively, there may be one second sliding rail 1222 to simplify the structure of the second sliding rail assembly 122, or there may be more than one second sliding rail 1222, so that the second sliding rail assembly 122 can guide the second part 132 and the second connecting rotating shaft 112 to slide more smoothly. The number of the third through holes 122d and the number of the second recesses 122g are the same as that of the second sliding rails 1222.

As illustrated in FIG. 5 and FIG. 14, in at least one implementation, the second sliding rail assembly 122 further includes a second elastic member 1224. The second elastic member 1224 is sleeved on the second sliding rail 1222. The second elastic member 1224 is disposed between the second connecting base 1221 and the second sliding base 1223 and can apply an elastic force on the second connecting base 1221 and the second sliding base 1223, to enable the second connecting base 1221 and the second sliding base 1223 to move relatively away from each other.

In one example, during switching the bendable mechanism 10 from the unfolded status to the folded status, the second elastic member 1224 is compressed. During switching the bendable mechanism 10 from the folded status to the unfolded status, the second elastic member 1224 extends. During unfolding of the bendable mechanism 10, the second elastic member 1224 can apply a push force against the second connecting base 1221 and the second sliding base 1223, such that the second connecting base 1221 and the second sliding base 1223 move relatively away from each other, so as to enable smooth unfolding of the flexible display device 100, and therefore the relative movement between the second connecting rotating shaft 112 and the second part 132 is relatively stable. When the bendable mechanism 10 is in the unfolded status, the second elastic member 1224 is in a natural state (that is, a state where no force is generated by the second elastic member 1224) or in a compressed state. The second elastic member 1224 being sleeved on the second sliding rail 1222 can save a space for stacking in the bendable mechanism 10 and improve the space utilization rate of the bendable mechanism 10, thereby facilitating installation of other elements.

In on example, one end of the second elastic member 1224 can be secured to the second connecting base 1221, and the other end of the second elastic member 1224 can be secured to the second sliding base 1223. Alternatively, both ends of the second elastic member 1224 are not fixed. Alternatively, one end of the second elastic member 1224 is not fixed, and the other end of the second elastic member 1224 is fixed to the second connecting base 1221 or the second sliding base 1223. According to implementations, the second elastic member 1224 is sleeved on the second sliding rail 1222, and both ends of the second elastic member 1224 are not fixed, which is convenient for disassembly and assembly. It can be understood that there is no restriction on the assembly manner of the second elastic member 1224, and there may have different assembly manners according to actual needs.

The second elastic member 1224 may have a straight-line shape. The straight-line shape refers to appearance of the second elastic member 1224 in the natural state. The cooperation of the second connecting base 1221, the second sliding rail 1222, and the second sliding base 1223 can position the second elastic member 1224, so that the second elastic member 1224 can be deformed in a preset direction (i.e., an extending direction of the second sliding rail 1222), enabling that the second connecting rotating shaft 112 and the second part 132 move relatively far away from each other under the guiding of the second sliding rail 1222. The second elastic member 1224 and the elastic member 148 may be elastic elements of the same type, such as springs, compression springs, and so on.

According to implementations, the direction in which the second elastic member 1224 is deformed is parallel to a sliding direction of the second sliding rail 1222. In this way, it is possible to ensure that the bendable mechanism 10 has high stability when the second connecting rotating shaft 112 and the second part 132 move relative to each other. In one example, when the bendable mechanism 10 is switched from the folded status to the unfolded status, the elastic force generated by the second elastic member 1224 in the compressed state is exerted on the second connecting base 1221 and the second sliding base 1223, and then the elastic force is transferred to the second connecting rotating shaft 112 and the second part 132, such that the second connecting rotating shaft 112 and the second part 132 can move relatively away from each other.

As illustrated in FIG. 5, FIG. 10, and FIG. 14, in at least one implementation, each second sliding rail 1222 includes a second sliding rod 122a and a second limitation portion 122b. The second sliding rod 122a passes through the second sliding base 1223. One distal end of the second sliding rod 122a is secured to the second connecting base 1221, and the other distal end of the second sliding rod 122a is coupled with the second limitation portion 122b. The second limitation portion 122b is operable to abut against the second sliding base 1223 to define a maximum distance of the relative movement between the second connecting rotating shaft 112 and the second part 132. The second sliding rod 122a and the second limitation portion 122b are integrally formed. Alternatively, the second sliding rod 122a and the second limitation portion 122b are separately formed. For example, the second limitation portion 122b is secured to the second sliding rod 122a by means of screwing or the second limitation portion 122b is secured to the second sliding rod 122a by gluing, welding, or other manners.

In one example, the second elastic member 1224 is sleeved on the second sliding rod 122a. The second sliding rod 122a is slidable in the second sliding base 1223. The second sliding base 1223 is disposed between the second elastic member 1224 and the second limitation portion 122b.

When the second connecting rotating shaft 112 and the second part 132 move relatively close to each other, the second limitation portion 122b and the second sliding base 1223 move relatively away from each other, and the second elastic member 1224 is compressed by the second sliding base 1223. When the second connecting rotating shaft 112 and the second part 132 move relatively away from each other, the second limitation portion 122b and the second sliding base 1223 move relatively close to each other, and the second elastic member 1224 gradually extends until the second elastic member 1224 reaches a natural state (or another compressed state). In addition, the second limitation portion 122b can prevent the second sliding rod 122a and the second sliding base 1223 from being detached from each other when the second connecting rotating shaft 112 and the second part 132 move relatively away from each other. A cross-sectional area of the second limitation portion 122b is larger than that of the third through hole 122d, so as to prevent the second limitation portion 122b from passing through the third through hole 122d, thereby ensuring that the second limitation portion 122b can play a position limiting role.

It can be understood that the second sliding rail assembly 122 can be made of plastic or metal. For example, all elements of the second sliding rail assembly 122 are made of plastic. For another example, all elements of the second sliding rail assembly 122 are made of metal. For yet another example, some elements of the second sliding rail assembly 122 are made of metal, and the remaining elements of the second sliding rail assembly 122 are made of plastic. In this way, the second sliding rail assembly 122 can be made of various materials, such that a variety of demands can be achieved.

As illustrated in FIG. 5 and FIG. 10, in one example, there may be at least two second sliding rail assemblies 122. The at least two second sliding rail assemblies 122 are respectively coupled with the second connecting rotating shaft 112 and the second part 132. The second connecting rotating shaft 112 defines at least two second mounting grooves 1122 on a side facing the second part 132. Each of at least two second connecting bases 1221 is inserted in a corresponding second mounting groove 1122 in the second connecting rotating shaft 112.

As illustrated in FIG. 5, in at least one implementation, there may be two second sliding rail assemblies 122. The two second sliding rail assemblies 122 are symmetrically arranged on both sides of the central axis (V-V line) of the second connecting rotating shaft 112 and the second part 132, so that the second connecting rotating shaft 112 and the second part 132 can be coupled with each other relatively stably. Alternatively, there may be one second sliding rail assembly 122 to simplify the structure of the bendable mechanism 10, or there may be more than one second sliding rail assembly 122, to make a sliding connection between the second connecting rotating shaft 112 and the second part 132 to be more stable.

As illustrated in FIG. 5, FIG. 10, and FIG. 14, in at least one implementation, the first sliding rail assembly 124 includes a first connecting base 1241, a first sliding rail 1242, and a first sliding base 1243. The first connecting base 1241 is secured to the first connecting rotating shaft 116, and the first sliding base 1243 is secured to the first part 134. The first sliding rail 1242 is slidably coupled with the first sliding base 1243, and the first sliding rail 1242 is secured to the first connecting base 1241.

In one example, the first connecting base 1241 defines a third mounting hole 124e. The first connecting base 1241 can be secured to the first connecting rotating shaft 116 by screwing, that is, the first connecting base 1241 can be secured to the first connecting rotating shaft 116 by inserting a screw in the third mounting hole 124e. The first sliding base 1243 defines a fourth mounting hole 124f. The first sliding base 1243 can be secured to the first part 134 by screwing, that is, the first sliding base 1243 can be secured to the first part 134 by inserting a screw in the fourth mounting hole 124f. According to implementations, since first connecting base 1241 is fixed to the first connecting rotating shaft 116 via the screw, and the first sliding base 1243 is fixed to the first part 134 via the screw, it is convenient for disassembly and assembly. In addition, the bendable mechanism 10 has high stability. In addition, the first connecting base 1241 may be secured to the first connecting rotating shaft 116 by welding, gluing, riveting, or the like. The first sliding base 1243 may be secured to the first part 134 by welding, gluing, riveting, or the like.

The first sliding base 1243 defines at least one second through hole 124d. Each first sliding rail 1242 passes through a corresponding second through hole 124d to be slidably coupled with the first sliding base 1243. The first sliding base 1243 can move along the first sliding rail 1242, resulting in relative movement between the first sliding rail 1242 and the first sliding base 1243, such that the first connecting base 1241 and the first sliding base 1243 can move relatively close to or relatively away from each other under the guiding of the first sliding rail 1242. The first connecting base 1241 defines a third recess 124g. One end of the first sliding rail 1242 is inserted in the third recess 124g and secured to the first connecting base 1241 by welding, gluing, screwing, or riveting. Therefore, the first connecting rotating shaft 116 and the first part 134 can also move relatively close to or away from each other under the guiding of the first sliding rail assembly 124.

As illustrated in FIG. 11, the first connecting rotating shaft 116 defines a first mounting groove 1162 at a position facing the first connecting base 1241. The first connecting base 1241 is inserted in the first mounting groove 1162, which improves the space utilization of the first connecting rotating shaft 116 and ensures that the first connecting rotating shaft 116 has a relatively smooth surface, facilitating the subsequent deployment of the flexible screen assembly 20.

As illustrated in FIG. 14, in one example, the first sliding rail assembly 122 includes at least two first sliding rails 1242 that are parallel to each other. The at least two first sliding rails 1242 are operable to guide relative movement between the rotating shaft assembly 11 and the first part 134 (the first sliding member 1342).

The at least two first sliding rails 1242 being arranged in parallel can ensure that each first sliding rail 1242 can slide in the first sliding base 1243 smoothly, so that the movement between the rotating shaft assembly 11 and the first part 134 is relatively stable and smooth. It can be understood that there may be multiple first sliding rails 1242 that are arranged in parallel. The multiple first sliding rails 1242 (arranged in parallel) are spaced apart from each other and disposed on the first sliding base 1243 and the first connecting base 1241. Alternatively, the first sliding rail assembly 124 includes one first sliding rail 1242.

It can be understood in at least one implementation, the sliding rail assembly 12 may include at least two sliding rails (e.g., at least two second sliding rails 1222, at least two first sliding rails 1242, etc.) that are arranged in parallel. The at least two sliding rails (e.g., at least two second sliding rails 1222, at least two first sliding rails 1242, etc.) are operable to guide relative movement between the rotating shaft assembly 11 and the casing 13. Since the relative movement between the rotating shaft assembly 11 and the casing 13 are guided by the at least two sliding rails arranged in parallel, the relative movement between the rotating shaft assembly 11 and the casing 13 may have high stability.

According to implementations, each first sliding rail assembly 124 includes one first connecting base 1241, one first sliding base 1243, and two first sliding rails 1242. Alternatively, there may be one first sliding rail 1242 to simplify the structure of the first sliding rail assembly 124, or there may be more than one first sliding rail 1242, to make relative sliding between the first connecting rotating shaft 116 and the first part 134 be relatively stable under the guiding of the first sliding rail assembly 124.

As illustrated in FIG. 5 and FIG. 14, the first part 134 includes a first sliding member 1342 and a second sliding member 1344. The first sliding rail assembly 124 further includes a first elastic member 1244. The first elastic member 1244 is sleeved on the first sliding rail 1242. The first elastic member 1244 is disposed between the first connecting base 1241 and the first sliding base 1243 and can apply an elastic force on the first connecting base 1241 and the first sliding base 1243, to enable the first connecting base 1241 and the first sliding base 1243 to move relatively away from each other.

In one example, during switching the bendable mechanism 10 from the unfolded status to the folded status, the first elastic member 1244 is compressed. During switching the bendable mechanism 10 from the folded status to the unfolded status, the first elastic member 1244 extends. During unfolding of the bendable mechanism 10, the first elastic member 1244 can apply a push force against the first connecting base 1241 and the first sliding base 1243, such that the first connecting base 1241 and the first sliding base 1243 move relatively away from each other, so as to enable smooth unfolding of the flexible display device 100, thereby making relative movement between the first connecting rotating shaft 116 and the first part 134 be relatively stable. When the bendable mechanism 10 is in the unfolded status, the first elastic member 1244 is in a natural state (that is, a state where no force is generated by the first elastic member 1244) or in a compressed state. The first sliding base 1243 is secured to the first sliding member 1342, and the first elastic member 1244 is sleeved on the first sliding rail 1242 to save a space for stacking in the bendable mechanism 10 and improve the space utilization rate of the bendable mechanism 10, thereby facilitating installation of other elements.

In one example, one end of the first elastic member 1244 can be secured to the first connecting base 1241, and the other end of the first elastic member 1244 can be secured to the first sliding base 1243. Alternatively, both ends of the first elastic member 1244 are not fixed. Alternatively, one end of the first elastic member 1244 is not fixed, and the other end of the first elastic member 1244 is fixed to the first connecting base 1241 or the first sliding base 1243. According to implementations, the first elastic member 1244 is sleeved on the first sliding rail 1242, and both ends of the first elastic member 1244 are not fixed, which is convenient for disassembly and assembly. It can be understood that there is no restriction on the assembly manner of the first elastic member 1244, and there may have different assembly manners according to actual needs.

The first elastic member 1244 may have a straight-line shape. The straight-line shape refers to appearance of the first elastic member 1244 in the natural state. The cooperation of the first connecting base 1241, the first sliding rail 1242, and the first sliding base 1243 can position the first elastic member 1244, so that the first elastic member 1244 can be deformed in a preset direction (i.e., an extending direction of the first sliding rail 1242), such that the first connecting rotating shaft 116 and the first part 134 move relatively away from each other under the guiding of the first sliding rail 1242. The second elastic member 1224, the first elastic member 1244, and the elastic member 148 may be elastic elements of the same type, such as springs, compression springs, and so on.

According to implementations, the direction in which the first elastic member 1244 is deformed is parallel to a sliding direction of the first sliding rail 1242. In this way, it is possible to ensure that the bendable mechanism 10 has high stability when the first connecting rotating shaft 116 and the first part 134 move relative to each other. In one example, when the bendable mechanism 10 is switched from the folded status to the unfolded status, the elastic force generated by the first elastic member 1244 in the compressed state is exerted on the first connecting base 1241 and the first sliding base 1243, and then the elastic force is transferred to the first connecting rotating shaft 116 and the first sliding member 1342, such that the first connecting rotating shaft 116 and the first sliding member 1342 can move relatively away from each other.

As illustrated in FIG. 5, FIG. 10, and FIG. 14, in at least one implementation, each first sliding rail 1242 includes a first sliding rod 124a and a first limitation portion 124b. The first sliding rod 124a passes through the first sliding base 1243. One distal end of the first sliding rod 124a is secured to the first connecting base 1241, and the other distal end of the first sliding rod 124a is coupled with the first limitation portion 124b. The first limitation portion 124b is operable to abut against the first sliding base 1243 to define a maximum distance of the relative movement between the first connecting rotating shaft 116 and the first sliding member 1342. The first sliding rod 124a and the first limitation portion 124b are integrally formed. Alternatively, the first sliding rod 124a and the first limitation portion 124b are separately formed. For example, the first limitation portion 124b is secured to the first sliding rod 124a by means of screwing or the first limitation portion 124b is secured to the first sliding rod 124a by gluing, welding, or other manners.

In one example, the first elastic member 1244 is sleeved on the first sliding rod 124a. The first sliding rod 124a is slidable in the first sliding base 1243. The first sliding base 1243 is disposed between the first elastic member 1244 and the first limitation portion 124b.

When the first connecting rotating shaft 116 and the first sliding member 1342 move relatively close to each other, the first limitation portion 124b and the first sliding base 1243 move relatively away from each other, and the first elastic member 1244 is compressed by the first sliding base 1243. When the first connecting rotating shaft 116 and the first sliding member 1342 move relatively away from each other, the first limitation portion 124b and the first sliding base 1243 move relatively close to each other, and the first elastic member 1244 gradually extends until the first elastic member 1244 reaches a natural state (or another compressed state). In addition, the first limitation portion 124b can prevent the first sliding rod 124a and the first sliding base 1243 from being detached from each other when the first connecting rotating shaft 116 and the first sliding member 1342 move relatively far away from each other. A cross-sectional area of the first limitation portion 124b is larger than that of the second through hole 124d, so as to prevent the first limitation portion 124b from passing through the second through hole 124d, thereby ensuring that the first limitation portion 124b can play a position limiting role.

It can be understood that the first sliding rail assembly 124 can be made of plastic or metal. For example, all elements of the first sliding rail assembly 124 are made of plastic. For another example, all elements of the first sliding rail assembly 124 are made of metal. For yet another example, some elements of the first sliding rail assembly 124 are made of metal, and the remaining elements of the first sliding rail assembly 124 are made of plastic. In this way, the first sliding rail assembly 124 can be made of various materials, such that various demands can be achieved.

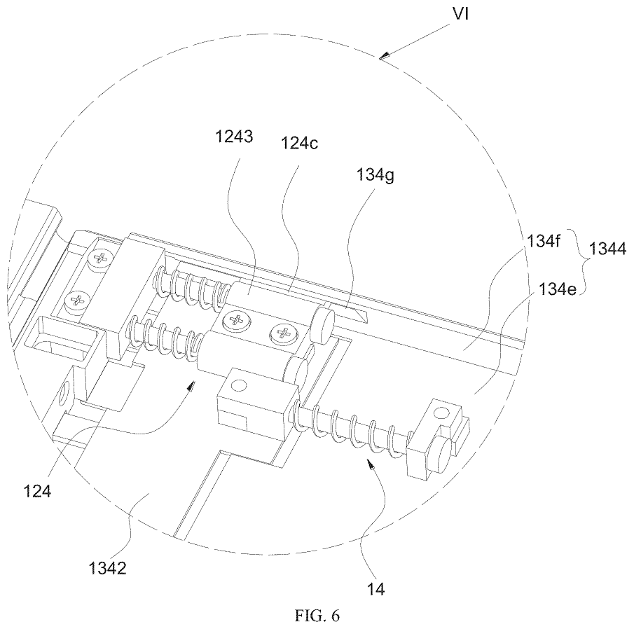

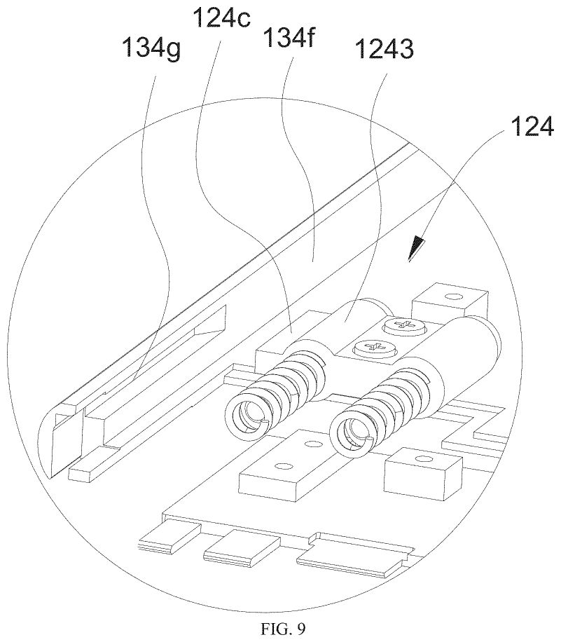

As illustrated in FIG. 6, FIG. 8, and FIG. 9, in at least one implementation, the second sliding member 1344 includes a bottom plate 134e and a side plate 134f protruding vertically from the bottom plate 134e. The side plate 134f defines a guide groove 134g. A guide block 124c is formed on a side of the first sliding base 1243 close to the side plate 134f, and the guide block 124c is inserted in and slidable in the guide groove 134g, enabling the second sliding member 1344 and the first sliding rail assembly 124 to slide relative to each other. In one example, the guide groove 134g has a length that is larger than the maximum distance L2 between the first sliding member 1342 and the second sliding member 1344.

In one example, the guide groove 134g being defined on the side plate 134f is beneficial to cooperate with the guide block 124c formed on the first sliding base 1243. The guide block 124c is inserted in the guide groove 134g, which is beneficial to reduce a space for stacking in the bendable mechanism 10 and improve the space utilization rate of the bendable mechanism 10, thereby facilitating installation of other elements of the bendable mechanism 10 and the flexible display device 100. In addition, the sliding connection between the guide block 124c and the guide groove 134g is relatively stable.

In one example, the guide grooves 134g may be defined on the side plates 134f at two sides of the central axis of the second sliding member 1344. The number of the guide grooves 134g is the same as that of the first sliding bases 1243, so that at both sides of the second sliding member 1344, the first sliding base 1243 cooperates with the guide groove 134g to perform guiding, and thus the second sliding member 1344 can slide relatively smoothly.

As illustrated in FIG. 5 and FIG. 10, in one example, there may be at least two first sliding rail assemblies 124. The at least two first sliding rail assemblies 124 respectively slidably connect the first connecting rotating shaft 116 with the second sliding member 1344. In one example, the first connecting rotating shaft 116 defines at least two first mounting grooves 1162 on a side facing the second sliding member 1344.

Each first connecting base 1241 is inserted in one first mounting groove 1162 in the first connecting rotating shaft 116. Referring to FIG. 5, in an implementation of the disclosure, two first sliding rail assemblies 124 are illustrated. The two first sliding rail assemblies 124 are symmetrically arranged on both sides of the central axis (V-V line) of the first connecting rotating shaft 116 and the first sliding member 1342, such that the first connecting rotating shaft 116 and the first sliding member 1342 can be coupled with each other relatively stably. In one example, there may be one first sliding rail assembly 124 to simplify the structure of the bendable mechanism 10. In another example, there may be more than one first sliding rail assembly 124 to make a sliding connection between the first connecting rotating shaft 116 and the first sliding member 1342 more stable.

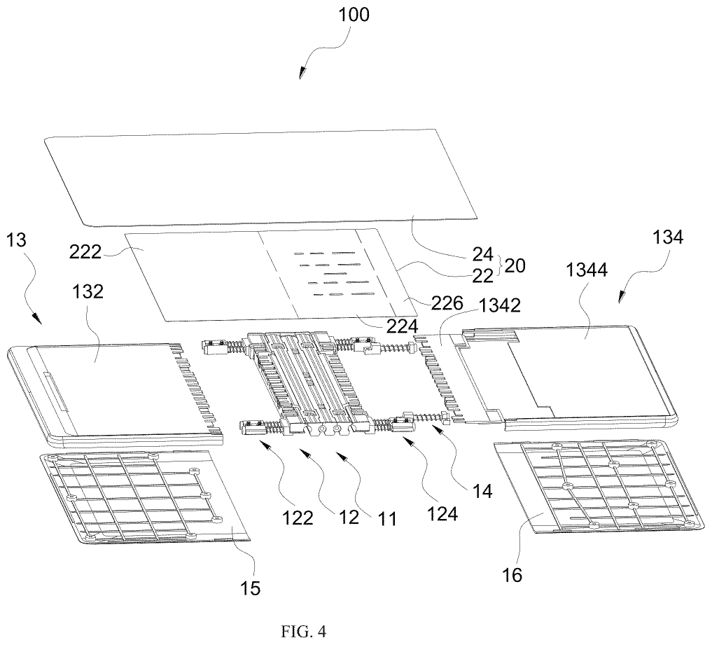

As illustrated in FIG. 4 and FIG. 5, in one example, the bendable mechanism 10 further includes a first cover 16 and a second cover 15. The second cover 15 and the second part 132 define a second receiving space (not illustrated), and the first cover 16 and the first part 134 define a first receiving space (not illustrated). The second sliding base 1223 and the second sliding rail 1222 are received in the second receiving space. The first sliding base 1243, the first sliding rail 1242, and the guide rail assembly 14 are received in the first receiving space. The second receiving space and the first receiving space can also be used to receive the other elements of the bendable mechanism 10 and the flexible display device 100. The cooperation of the second cover 15 and the second part 132 can protect internal structures such as the second sliding rail assembly 122, and the cooperation of the first cover 16 and the first part 134 can protect internal structures such as the first sliding rail assembly 124 and the guide rail assembly 14, to avoid that dust and moisture enter the internal structures. Furthermore, the internal structures of the flexible display device 100 are invisible to the user, which is beneficial to beautifying the flexible display device 100 and enhancing the structural integrity of the flexible display device 100.

As illustrated in FIG. 10 and FIG. 11, in one example, the middle rotating shaft structure 114 includes a first rotating shaft 1142, a second rotating shaft 1144, and a third rotating shaft 1146. The first rotating shaft 1142 and the third rotating shaft 1146 are rotatably coupled with two opposite sides of the second rotating shaft 1144, respectively. The first rotating shaft 1142 is coupled with the second connecting rotating shaft 112 and the second rotating shaft 1144. The third rotating shaft 1146 is coupled with the first connecting rotating shaft 116 and the second rotating shaft 1144.

In one example, the first rotating shaft 1142, the second rotating shaft 1144, and the third rotating shaft 1146 are hinged with each other. In this way, the first rotating shaft 1142, the second rotating shaft 1144, and the third rotating shaft 1146 can form a multi-axes combination, and the multi-axes combination can meet requirements on a bending angle of the bendable mechanism 10 and the flexible display device 100. The interior of the first rotating shaft 1142, the second rotating shaft 1144, and the third rotating shaft 1146 can be hollowed out, which can reduce the overall weight of the middle rotating shaft structure 114, such that it is conducive to make the bendable mechanism 10 and the flexible display device 100 be thin, thereby facilitating carrying and use.

Certainly, detailed implementation of the middle rotating shaft structure 114 is not limited to the implementation discussed above and can be set according to actual needs. In one example, fewer or more rotating shafts can be adopted. It can be understood that fewer rotating shafts can make the structure of the middle rotating shaft structure 114 simpler, which can reduce the production cost and the complexity of assembly and disassembly. More rotating shafts can make the middle rotating shaft structure 114 have more bending angles, so as to improve change in bending angle and bending shape of the bending mechanism 10, thereby further causing the flexible display device 100 to have various bending styles.

The interior of the second connecting rotating shaft 112, the first connecting rotating shaft 116, and the middle rotating shaft structure 114 may be hollowed out, so that the rotating shaft assembly 11 has a certain strength and is of light, which is beneficial to make the bending mechanism 10 and the flexible display device 100 be thin, thereby facilitating carrying and use.

In one example, the second connecting rotating shaft 112 and the middle rotating shaft structure 114 rotate synchronously with the first connecting rotating shaft 116. In this way, it is possible to smoothly unfold and fold the bendable mechanism 10, and thus the unfolding and folding of the flexible display device 100 are smooth, thereby improving the user experience. In addition, a joint between the second connecting rotating shaft 112 and the middle rotating shaft structure 114 can be provided with a reverse limiting structure (not illustrated) and/or a joint between the middle rotating shaft structure 114 and the first connecting rotating shaft 116 can be provided with a reverse limiting structure (not illustrated), which can avoid reverse rotation of the rotating shaft assembly 11. For example, it is possible to prevent the rotating shaft assembly 11 from further being bent towards the unfolding direction when the rotating shaft assembly 11, the bendable mechanism 10, or the flexible display device 100 is fully unfolded or in a 0-degree state, thereby avoiding damaging the bendable mechanism 10 by wrong operations.

As illustrated in FIG. 10, in an implementation of the disclosure, the rotating shaft assembly 11 in the unfolded status is substantially rectangular. There is no restriction on the shape of the rotating shaft assembly 11, which can be set according to actual needs in other implementations.

As illustrated in FIG. 8, FIG. 10, and FIG. 11, in some implementations, the casing 13 includes a first side portion 136 facing the rotating shaft assembly 11, and the rotating shaft assembly 11 includes a second side portion 118 facing the casing 13. The first side portion 136 is provided with a first guide structure 1362, the second side portion 118 is provided with a second guide structure 1182. The first guide structure 1362 and the second guide structure 1182 can be coupled with each other and cooperatively guide relative movement between the casing 13 and the rotating shaft assembly 11.

In one example, when the bendable mechanism 10 is in the unfolded status, a distance between the first guide structure 1362 and the second guide structure 1182 is maximum. In this case, the first guide structure 1362 and the second guide structure 1182 may be partially engaged with each other to facilitate guiding the relative movement between the rotating shaft assembly 11 and the casing 13 when the rotating shaft assembly 11 is bent. During switching the bendable mechanism 10 from the unfolded status to the folded status, the first guide structure 1362 and the second guide structure 1182 move close to each other and can be further engaged with each other, to further guide the relative movement between the casing 13 and the rotating shaft assembly 11. The first guide structure 1362 and the second guide structure 1182 each may include multiple protrusions. The multiple protrusions of the first guide structure 1362 and the multiple protrusions of the second guide structure 1182 are misaligned and fit to gaps between two corresponding protrusions. In one example, the first guide structure 1362 and the second guide structure 1182 both have comb-shaped structures that can be snapped and coupled with each other, and the first guide structure 1362 and the second guide structure 1182 can move relative to each other. The interlocking and engagement of the comb-shaped structures has a relatively guiding effect, and the relative movement between the casing 13 and the rotating shaft assembly 11 is also relatively smooth, and thus the casing 13 and the rotating shaft assembly 11 are not easy to be misaligned.

Moreover, the first guide structures 1362 can be arranged on the second part 132 and the first sliding member 1342, and the second guide structures 1182 can be arranged on a side surface of the second connecting rotating shaft 112 facing the casing 13 and a side surface of the first connecting rotating shaft 116 facing the casing 13. The cooperation of the first guide structure 1362 and the second guide structure 1182 guides the relative sliding between the second part 132 and the second connecting rotating shaft 112 as well as the relative sliding between the first sliding member 1342 and the first connecting rotating shaft 116.

As illustrated in FIG. 10 to FIG. 12, the first guide structure 1362 includes an engaging portion 136a, and the second guide structure 1182 includes an engaging member 118a engaged with the engaging portion 136a. In one example, the engaging portion 136a is a first protrusion block 136b extending toward the rotating shaft assembly 11, and the first protrusion block 136b defines a first receiving groove 136c. The engaging member 118a is a second receiving groove 118b that is recessed in a direction opposite the casing 13 and faces the first protrusion block 136b. A second protrusion block 118c protrudes from the second receiving groove 118b, and the second protrusion block 118c extends toward the casing 13 and faces the first receiving groove 136c. When the bendable mechanism 10 is in the folded status, the first protrusion block 136b is engaged with the second receiving groove 118b, and the first receiving groove 136c is engaged with the second protrusion block 118c. In this way, due to engagement between the first protrusion block 136b and the second receiving groove 118b, and engagement between the first receiving groove 136c and the second protrusion block 118c, the relative movement between the second part 132 and the second connecting rotating shaft 112 as well as the relative sliding between the first sliding member 1342 and the first connecting rotating shaft 116 are relatively stable. In this case, the bendable mechanism 10 has a relatively stable structure, enabling the smooth unfolding and folding of the bendable mechanism 10.

As illustrated in FIG. 1 to FIG. 4, in an implementation of the disclosure, the flexible display device 100 includes the bendable mechanism 10 described in any of the above implementations and the flexible screen assembly 20 arranged on the bendable mechanism 10.

In the implementation of the disclosure, in the flexible display device 100, during bending the bendable mechanism 10, the rotating shaft assembly 11 and the first sliding member 1342 move relatively close to each other under the guiding of the sliding rail assembly 12, the first sliding member 1342 and the second sliding member 1344 move relatively close to each other under the guiding of the guide rail assembly 14, and the rotating shaft assembly 11 and the second part 132 move relative to each other, and thus the change in arc length of the bending portion of the rotating assembly 11 during bending the rotating shaft assembly 11 can be offset. As such, it is possible to prevent the flexible screen 24 installed on the bendable mechanism 10 from being damaged by stretching, such that the service life of the flexible screen 24 can be ensured. In addition, it is possible to enable the flexible screen 24 to be flattened when the rotating shaft assembly 11 is in the unfolded status.

When the flexible display device 100 is fully unfolded, the flexible display device 100 is substantially rectangular or rounded rectangular, and thus usage habits of the user can be satisfied and a relatively large display area can be provided. Certainly, when the flexible display device 100 is fully unfolded, the flexible display device being substantially in the shape of a rectangle or rounded rectangle is merely illustrative, which shall not be understood to limit the disclosure.

As illustrated in FIG. 4, in some implementations, the flexible screen assembly 20 includes a flexible support member 22 and a flexible screen 24. The flexible support member 22 is secured to the first sliding member 1342, and the flexible screen 24 is attached to a surface of the flexible support member 22 away from the first sliding member 1342.

In one example, the flexible support member 22 includes a first non-bendable region 222, a second non-bendable region 226, and a bendable region 224 coupled with the first non-bendable region 222 and the second non-bendable region 226.

The first non-bendable region 222, the second non-bendable region 226, and the bendable region 224 can be attached to the casing 13 in sections, and the flexible screen 24 can be attached to the flexible support member 22 and the first part 134 in sections. The first non-bendable region 222 is attached and fixed to the second part 132, the second non-bendable region 226 is attached and fixed to the first sliding member 1342, and the bendable region 224 is slidably attached to the rotating shaft assembly 11. The flexible screen 24 is attached and secured to the first non-bendable region 222 and the second sliding member 1344, and the flexible screen 24 is slidably attached to the second non-bendable region 226 and the bendable region 224. The second part 132, the flexible support member 22, and the flexible screen 24 can simultaneously slide relative to the rotating shaft assembly 11. The flexible screen 24 is slidably rather than fixedly attached to the bendable region 224. When the rotating shaft assembly 11 is bent, a part of the flexible screen 24 which is slidably attached to the bendable region 224 is slidable relative to the flexible support member 22, and thus a risk that the flexible screen 24 is damaged by stretching can be reduced. The second non-bendable region 226 is attached to the first sliding member 1342 and slidable relative to the rotating shaft assembly 11. A part of the flexible screen 24 extending to the first part 134 is attached to the second sliding member 1344 and slidable relative to the first sliding member 1342.

When the rotating shaft assembly 11 is rotated, the flexible support member 22 drives the first sliding member 1342 and the second part 132 to move toward each other, so that a length of the bendable mechanism 10 in the folded status is the same as that in the unfolded status. In addition, since there is a radius difference between the flexible screen assembly 20 and the rotating shaft assembly 11, it is necessary to slide the second sliding member 1344 to cause a length change required for bending, so as to prevent the flexible screen 24 from being damaged by stretching. The flexible support member 22 being attached to the flexible screen 24 enables the flexible support member 22 to better support the flexible screen 24.

Corresponding parts of the flexible support member 22, the flexible screen 24, the second part 132, the first sliding member 1342, the second sliding member 1344, and the like can be attached together via media with certain adhesion capabilities such as optical adhesives and double-sided adhesive layers, and thus not only high fixing ability can be provided, but also thinning and integrity of the flexible display device 100 can be ensured.

In some implementations, the flexible support member 22 is made of titanium alloy, stainless steel, carbon fiber composite, or Kevlar. The above materials have at least one of high strength, good rigidity, low density, light weight, high thermal strength, and good corrosion resistance, so they are suitable for manufacturing the flexible support member 22.

In some implementations, the flexible screen 24 includes an organic light emitting diode (OLED) display. The OLED display has self-luminous organic electroluminescent diodes, which have the advantages of no backlight, high contrast, small thickness, wide viewing angle, and high response speed. Moreover, the OLED display can be used for a flexible panel and has a wide operating temperature and a relatively simple constructing and manufacturing process.

In the description of this specification, the terms “one implementation”, “certain implementations”, “exemplary implementations”, “examples”, “specific examples”, or “some examples” and the like means that the specific features, structures, materials, or characteristics described in connection with the implementations or examples are included in at least one implementation or example. In this specification, the schematic representations of the above-mentioned terms do not necessarily refer to the same implementation or example. Moreover, the described specific features, structures, materials, or characteristics can be combined in any one or more implementations or examples in a suitable manner.

Although the implementations of the disclosure have been illustrated and described, those of ordinary skill in the art can understand that various changes, modifications, and substitutions, and equivalent arrangements can be made to these implementations without departing from the principle and purpose of the disclosure. The scope of the disclosure is defined by the claims and their equivalents.

What is claimed is:

1. A bendable mechanism, comprising:
a casing;
a rotating shaft assembly; and
a sliding rail assembly connecting the casing with the rotating shaft assembly;
wherein the bendable mechanism is operable to be switched between an unfolded status and a folded status, wherein during switching the bendable mechanism from the unfolded status to the folded status, the rotating shaft assembly and the casing move relatively close to each other under the guiding of the sliding rail assembly, and during switching the bendable mechanism from the folded status to the unfolded status, the rotating shaft assembly and the casing move relatively away from each other under the guiding of the sliding rail assembly;
wherein the sliding rail assembly comprises at least two sliding rails that are disposed in parallel, wherein the at least two sliding rails are operable to guide relative movement between the rotating shaft assembly and the casing.

2. The bendable mechanism of claim 1, wherein the sliding rail assembly further comprises a connecting base and a sliding base, wherein the connecting base is fixed to the rotating shaft assembly, the sliding base is fixed to the casing, and the connecting base and the sliding base are movable relatively close to each other or away from each other under the guiding of the at least two sliding rails.

3. The bendable mechanism of claim 2, wherein the sliding rail assembly further comprises an elastic member, wherein the elastic member is disposed between the connecting base and the sliding base, wherein when the casing and the rotating shaft assembly move relatively close to each other, the elastic member is gradually compressed, and when the casing and the rotating shaft assembly move relatively away from each other, the elastic member gradually extends.

4. The bendable mechanism of claim 3, wherein
each of the at least two sliding rails comprises a sliding rod and a limitation portion, wherein the sliding rod passes through the sliding base, and the sliding rod has one distal end secured to the connecting base and the other distal end coupled with the limitation portion; and
the sliding base is operable to slide on the sliding rod between the limitation portion and the connecting base.

5. The bendable mechanism of claim 4, wherein
when the bendable mechanism is in the unfolded status, the casing and the rotating shaft assembly cooperatively define a maximum distance; and
the sliding rod has a length that is larger than the maximum distance between the casing and the rotating shaft assembly.

6. The bendable mechanism of claim 1, wherein
the rotating shaft assembly comprises a first connecting rotating shaft, a second connecting rotating shaft, and a middle rotating shaft structure, wherein the first connecting rotating shaft and the second connecting rotating shaft are rotatably coupled with two opposite sides of the middle rotating shaft structure, respectively;
the casing comprises a first part and a second part; and
the sliding rail assembly comprises a first sliding rail assembly and a second sliding rail assembly, wherein the first sliding rail assembly is coupled with the first connecting rotating shaft and the first part, and the second sliding rail assembly is coupled with the second connecting rotating shaft and the second part.

7. The bendable mechanism of claim 6, wherein
the first connecting rotating shaft defines a first mounting groove;
the first sliding rail assembly comprises a first connecting base, wherein the first connecting base is inserted in the first mounting groove;
the second connecting rotating shaft defines a second mounting groove; and
the second sliding rail assembly comprises a second connecting base, wherein the second connecting base is inserted in the second mounting groove.

8. The bendable mechanism of claim 6, wherein
the first part comprises a first sliding member and a second sliding member slidably connected to the first sliding member;
during switching the bendable mechanism from the unfolded status to the folded status, the first sliding member and the second sliding member move relatively close to each other, and during switching the bendable mechanism from the folded status to the unfolded status, the first sliding member and the second sliding member move relatively away from each other;
the first sliding rail assembly comprises a first sliding base, wherein the first sliding base is secured to the first sliding member.

9. The bendable mechanism of claim 8, wherein
a first guide portion is formed on a side of the first sliding member facing the second sliding member;
a second guide portion is formed on a side of the second sliding member facing the first sliding member;
when the bendable mechanism is in the unfolded status, the first guide portion and the second guide portion define a gap, and when the bendable mechanism is in the folded status, the first guide portion and the second guide portion engage with each other.

10. The bendable mechanism of claim 9, wherein the first guide portion has a stepped shape, and the second guide portion has an inverted stepped shape, wherein when the bendable mechanism is in the folded status, the first guide portion is engaged with the second guide portion.

11. The bendable mechanism of claim 8, wherein
the second sliding member comprises a bottom plate and a side plate protruding from the bottom plate, wherein the side plate defines a guide groove; and
a guide block is formed on a side of the first sliding base close to the side plate, wherein the guide block is inserted in and slidable in the guide groove, enabling the second sliding member and the first sliding rail assembly to slide relative to each other.

12. The bendable mechanism of claim 8, further comprising a guide rail assembly, wherein the guide rail assembly is slidably connected to the first sliding member and the second sliding member;
during switching the bendable mechanism from the unfolded status to the folded status, the first sliding member and the second sliding member move relatively close to each other under the guiding of the guide rail assembly; and
during switching the bendable mechanism from the folded status to the unfolded status, the first sliding member and the second sliding member move relatively away from each other under the guiding of the guide rail assembly.

13. The bendable mechanism of claim 12, wherein the guide rail assembly comprises a fixing member, a guide base, and a guide rail, wherein the fixing member is secured to the first sliding member, the guide base is secured to the second sliding member, the guide rail is slidably connected to the guide base, and the guide rail is secured to the fixing member.

14. The bendable mechanism of claim 13, wherein the guide rail assembly further comprises an elastic member, wherein the elastic member is disposed between the fixing member and the guide base, wherein when the first sliding member and the second sliding member move relatively close to each other, the elastic member is gradually compressed, and when the first sliding member and the second sliding member move relatively away from each other, the elastic member gradually extends.

15. The bendable mechanism of claim 13, wherein
the guide base defines a first through hole;
the guide rail comprises a guide rod and a limitation head, wherein the guide rod passes through the first through hole in the guide base, the guide rod has one distal end secured to the fixing member and the other distal end coupled with the limitation head;
the guide base is operable to slide on the guide rod between the limitation head and the fixing member.

16. The bendable mechanism of claim 15, wherein
when the bendable mechanism is in the unfolded status, the first sliding member and the second sliding member cooperatively define a maximum distance; and
the guide rod has a length that is larger than the maximum distance between the first sliding member and the second sliding member.

17. The bendable mechanism of claim 1, wherein
the casing comprises a first side portion facing the rotating shaft assembly, wherein the first side portion is provided with a first guide structure;
the rotating shaft assembly comprises a second side portion facing the casing, wherein the second side portion is provided with a second guide structure; and
the first guide structure and the second guide structure are operable to engage with each other and cooperatively guide relative movement between the casing and the rotating shaft assembly.

18. A flexible display device, comprising:
a bendable mechanism, wherein the bendable mechanism comprises:
a casing;
a rotating shaft assembly; and
a sliding rail assembly connecting the casing with the rotating shaft assembly;
wherein the bendable mechanism is operable to be switched between an unfolded status and a folded status, wherein during switching the bendable mechanism from the unfolded status to the folded status, the rotating shaft assembly and the casing move relatively close to each other under the guiding of the sliding rail assembly, and during switching the bendable mechanism from the folded status to the unfolded status, the rotating shaft assembly and the casing move relatively away from each other under the guiding of the sliding rail assembly;
wherein the sliding rail assembly comprises at least two sliding rails that are disposed in parallel, wherein the at least two sliding rails are operable to guide relative movement between the rotating shaft assembly and the casing;
a flexible support member connected to the bendable mechanism; and
a flexible screen, wherein the flexible screen is attached to a surface of the flexible support member away from the bendable mechanism.

19. The flexible display device of claim 18, wherein the flexible support member is secured to the casing, and the flexible support member is slidably connected to the rotating shaft assembly.

20. The flexible display device of claim 19, wherein
the flexible support member comprises a first non-bendable region, a second non-bendable region, and a bendable region coupled with the first non-bendable region and the second non-bendable region; and
the flexible screen is secured to one of the first non-bendable region and the second non-bendable region, and the flexible screen is slidably connected to the bendable region.
